(19) United States
(12) Patent Application Publication
(10) Pub. No.: US 2005/0149811 A1
(43) Pub. Date: Jul. 7, 2005

(54) System and method of ensuring quality control of software

(76) Inventor: Allen Lubow, Brooklyn, NY (US)

Correspondence Address: BROWN, RAYSMAN, MILLSTEIN, FELDER & STEINER LLP, 900 THIRD AVENUE, NEW YORK, NY, 10022, US

(21) Appl. No.: 10/991,090

(22) Filed: Nov. 17, 2004

Related U.S. Application Data
(60) Provisional application No. 60/520,827, filed on Nov. 17, 2003.

(51) Int. Cl. G05B 13/02; H04L 1/00; G06F 11/00; G06F 11/30; H03M 13/00; G08C 25/00

(52) U.S. Cl. 714/746

(57) ABSTRACT

A system and method is provided that includes verifying that a computer system generates an output file that conforms to a model output file comprising one or more expected output results. The system and method comprises generating one or more first output results by applying one or more input parameters to a first computer system. It is then verified whether the one or more first output results match the one or more expected results. Upon verification, one or more second output results are then generated by applying the input parameters to a second computer system. The one or more first output results are then verified by electronically comparing them with the one or more second output results. It is verified that the computer system generates an output file that conforms to the model output file and generates a desired result.

### CROSS-REFERENCE TO RELATED APPLICATIONS

The present application also claims the benefit under 35 U.S.C. § 119(e) from provisional patent application No. 60/520,827, filed Nov. 17, 2003, the contents of which is incorporated by reference herein its entirety.

### COPYRIGHT AND LEGAL NOTICES

A portion of the disclosure of this patent document contains material which is subject to copyright protection. The copyright owner has no objection to the facsimile reproduction by anyone of the patent document or the patent disclosure, as it appears in the Patent and Trademark Office patent files or records, but otherwise reserves all copyrights whatsoever.

### BACKGROUND OF THE INVENTION

The present invention relates generally to a system and method for testing software, and more particularly to comparing generated computer files with a model file for detecting errors and discrepancies in the generated computer files.

### SUMMARY OF THE INVENTION

According to an embodiment of the present invention, a method is provided for verifying a computer system. The method comprises generating one or more first output results by applying one or more input parameters to a first computer system. It is then verified that the one or more first output results match the one or more expected results. One or more second output results are then generated by applying the input parameters to a second computer system. The one or more first output results are then verified by electronically comparing them with the one or more second output results.

According to another embodiment of the present invention, the first computer system and the second computer system may be the same. Alternatively, the first computer system and the second computer system may be different.

According to another embodiment of the present invention, a result based on the electronic comparison is reported, whereby the reported result indicates an error based upon the electronic comparison detecting a discrepancy between the verified one or more first output results with the one or more second output results.

According to another embodiment of the present invention, the one or more first output results comprise at least one graphic output, where the graphic output may include a machine-readable symbol graphic.

According to another embodiment of the present invention, electronically comparing the verified one or more first output results with the one or more second output results comprises a digital bit-by-bit comparison between the one or more first output results and the one or more second output results. The digital bit-by-bit comparison comprises generating a checksum between each bit-by-bit component within the verified one or more first output results and the one or more second output results.

According to another embodiment of the present invention, verifying that the one or more first output results match the one or more expected results comprises visually comparing the one or more first output results with the one or more expected results.

According to another embodiment of the present invention, verifying that the one or more output results match the one or more expected results comprises using a device to determine that the one or more first output results match the one or more expected results. The device may include, for example, a bar code verifier device.

According to another embodiment of the present invention, additional parameters may be added to the one or more input parameters based on modifications to the second computer system, wherein the additional parameters generate additional one or more first output results.

According to another embodiment of the present invention, the additional one or more first output results are verified to ensure that the additional one or more first output results match additional one or more expected results.

According to another embodiment of the present invention, a method is provided for verifying a first computer system implemented by a second computer system. The method comprises generating at the first computer system one or more first output results by applying one or more input parameters to the first computer system. It is then verified at the first computer system that the one or more first output results match one or more expected results. At the second computer one or more second output results are generated by applying the one or more input parameters to the second computer system. At the second computer system, the verified one or more first output results are electronically compared with the one or more second output results.

According to another embodiment of the present invention, a system comprising a first computer system is provided for verifying a second computer system. The first computer system is programmed to generate one or more first output results by applying one or more input parameters to the first computer system. It is then verified that the one or more output results match one or more expected results. One or more second output results are then generated by applying the one or more input parameters to the second computer system. The verified one or more first output results are then electronically compared with the one or more second output results.

According to another embodiment of the present invention, a computer readable medium or media is provided having programming. When the programming is executed by one or more computer systems it causes the one or more computer systems to generate one or more first output results by applying one or more input parameters to the first computer system. It also verifies that the one or more first output results match one or more expected results. One or more second output results are then generated by applying the one or more input parameters to the second computer system. The verified one or more first output results are electronically compared with the one or more second output results.

According to another embodiment of the present invention, a computer verification system is provided. The system comprises a means for generating one or more first output results by applying one or more input parameters to a first computer system. It then provides a means for verifying that the one or more first output results match the one or more expected results. A means for generating one or more second output results by applying the input parameters to a second computer system is then provided. Also provided, is a means for electronically comparing the verified one or more first output results with the one or more second output results.

### BRIEF DESCRIPTION OF DRAWINGS

The invention is illustrated in the figures of the accompanying drawings, which are meant to be exemplary and not limiting, and in which like references are intended to refer to like or corresponding parts.

FIG. 1 is an operational flowchart associated with computer system according to an embodiment of the present invention.

FIG. 2a illustrates an example of a first operational step associated with a software quality control system according to an embodiment of the present invention.

FIG. 2b illustrates an example of a second operational step associated with a software quality control system according to an embodiment of the present invention.

FIG. 2c illustrates an example of a third operational step associated with a software quality control system according to an embodiment of the present invention.

### DETAILED DESCRIPTION

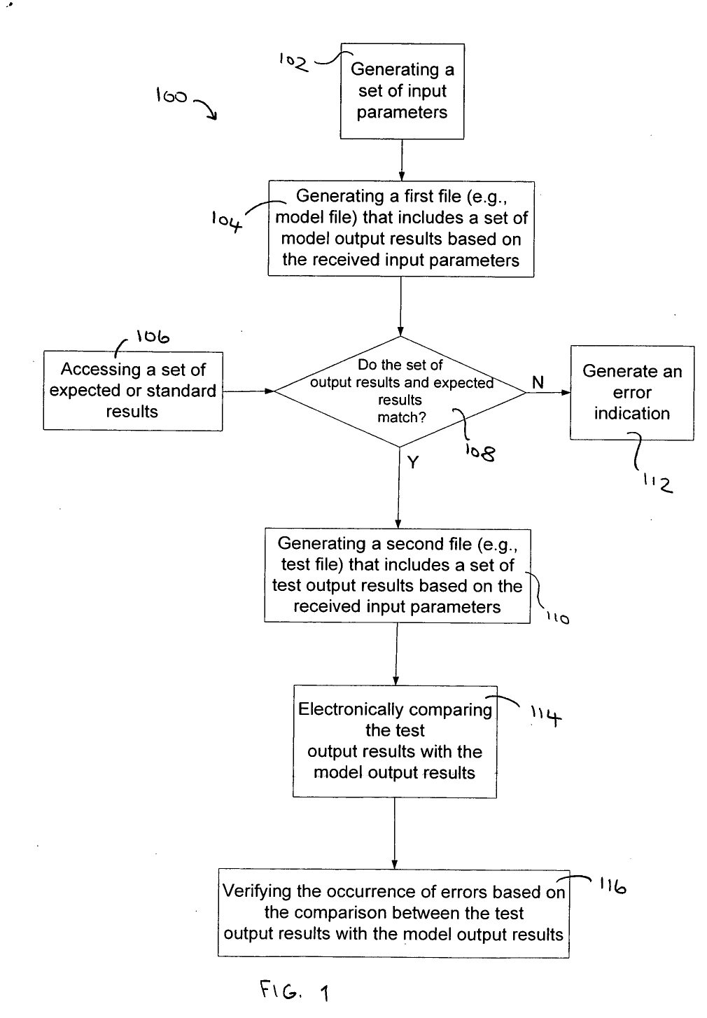

FIG. 1 illustrates an operational flow chart 100 for a method of providing software quality control in a computer system according to an embodiment of the present invention. The computer system may comprise hardware, software, or a combination of both hardware and software. Also, the hardware may include one or more computer or processing devices. Similarly, the software may include one or one programs that are executable on the one or more computers or processing devices. At step 102, a set of input parameters are provided, where the input parameters may, for example, be stored as one or more files within a storage medium (e.g., CD, RAM, ROM, etc.). At step 104, the set of input parameters are used to generate a set of model or reference output results. For example, the input parameters may be input to a first computer or processing device running a first computer program. The first computer program may then generate the set of model or reference output results based on the received input parameters.

At step 106, a set of expected or standard results are accessed, whereby the expected results may, for example, include industry standard requirements (e.g., bar code formats), or a known set of required criteria. The expected results may include, generally, any set of results that the user of the system requires or knows to be correct. At step 108, the generated model output results are verified by comparing them to the set of expected or standard results. Once the model output results are verified, they may serve as a reference or model output against which other output results may be compared. The verification process may, for example, involve a visual inspection of the model output results and the expected or standard results. For example, a visual inspection may be carried out when the model output results comprise graphics such as machine-readable symbols (e.g., bar codes). In this case, the model output results comprising the graphical symbols are visually inspected in order to verify that they are within standard, known, or required specification. Alternatively, various test and verification devices may be used to compare and verify that the model output results conform with the expected results. For example, if the model output results comprise bar code symbology graphics, a bar code verifier device may be used to ensure that the generated symbols are within specification, as defined by bar code known standards. Conversely, if the comparison between output results fail to match, it may be established that, for example, the computer program or data source generating the other output results is contaminated and/or includes some form of error (e.g., programming error).

If at step 108 the set of expected or standard results match the generated model output, at step 110 a second set of test output results are generated based on the set of input parameters. For example, the input parameters may be input to the first computer or processing device running on the first computer program. The first computer program may then generate the set of test output results. It may also be possible to generate the test output results by applying the input parameters to a second computer or processing device running another copy of the first computer program. If the comparison between model and expected output results match, the model output results may then be used to establish whether other output results from one or more computer programs conform with the expected requirements, as set forth by the model output results.

If at step 108, the set of expected or standard results fail to match the generated model output, at step 112 an error indication is generated. In this case, for example, the computer program executing the input parameters may need additional programming and/or modification. Also, it is possible that the input parameters may require additions and/or modifications.

At step 114, the test output results are electronically (e.g., digitally) compared with the model output results. At step 116, it is verified whether the electronic comparison indicates any discrepancies between the test output results and the model output results. If one or more discrepancies exist, it may indicate that the computer program or system that generated the test output results is producing an erroneous result. This erroneous result may be, for example, due to programming issues (software additions, edits, etc.), hardware issues (change of hardware), computer viruses, corrupted files, and/or other relevant factors. Based on the detected error, a report may be generated, whereby, for example, a report summarizing the error(s) is generated.

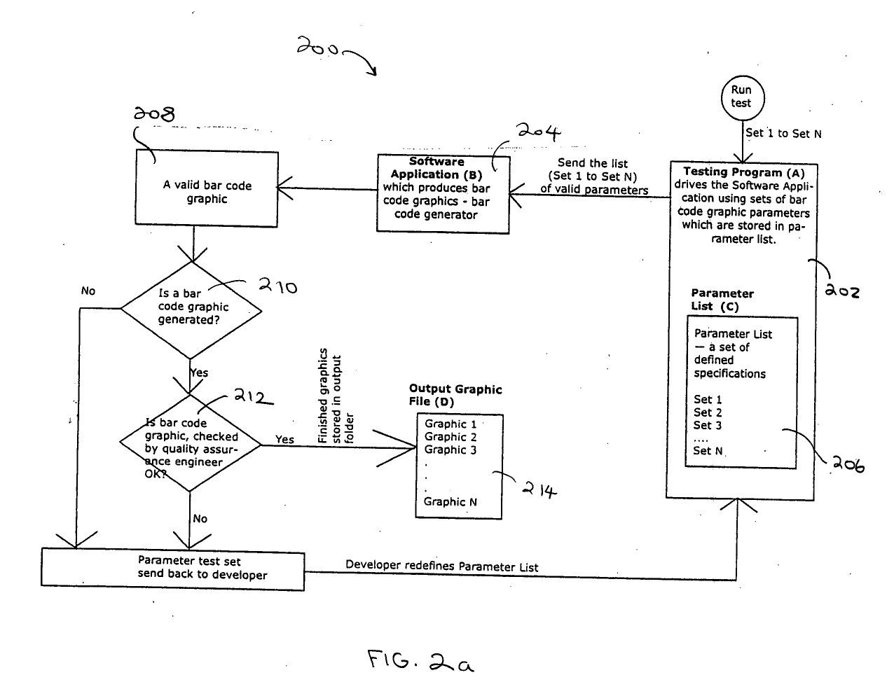

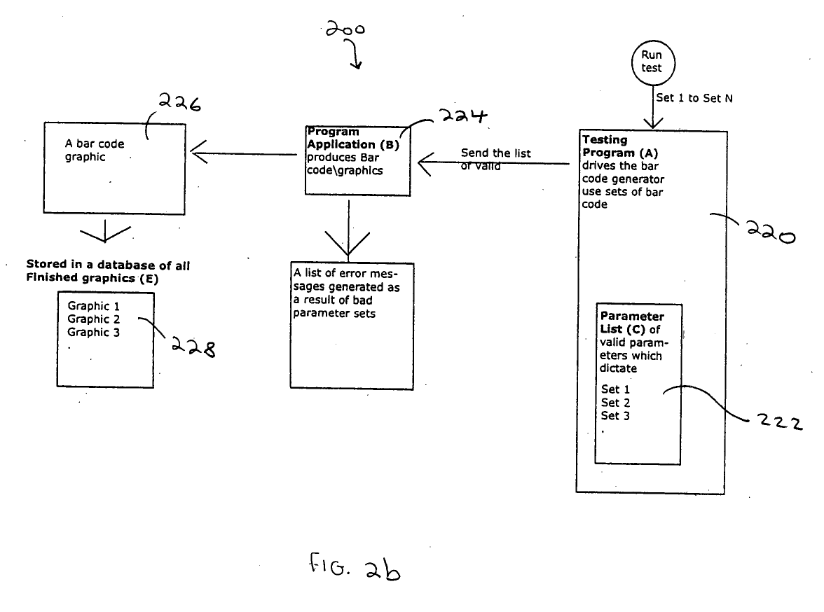

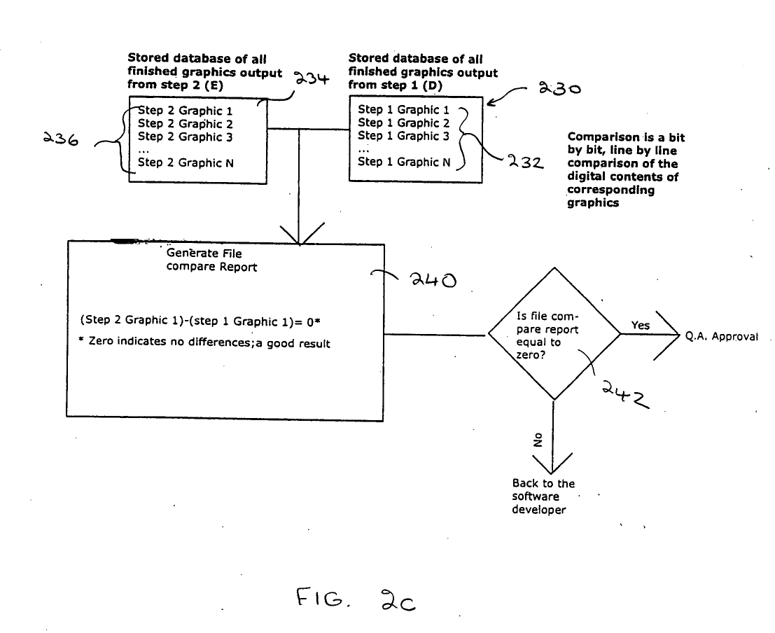

FIG. 2a illustrates an example of a first operational step associated with a software quality control system 200 for bar code generation software according to an embodiment of the present invention. A software-testing program 202 drives an application program 204 (e.g., bar code generation application program) with a given set of input parameters 206. Once the application program 204 receives the input parameters 206, it generates a set of graphics in a model Output file 208. The set of graphics are then evaluated in order to determine whether program 204 generated graphics having the correct or desired specification.

At step 210, it is determined whether one more graphics were generated by program 208. If the graphics are generated, at step 212 each graphic is checked in order to determine that it is within a given or required specification. For example, bar code graphics have numerous attributes that need to be checked and verified. In the given example, the bar code graphics may be visually checked to make sure that each bar code graphic representing a particular symbology conforms to the correct standard. Alternatively, the graphics may be verified electronically by, for example, a bar code verifier, a light meter, etc. If at step 212, the generated graphics are correct and conform to the required standards, the generated graphics are stored in a model output file 214. The system 200 then uses this model output file to evaluate the integrity of the application program 204 as a software or computer system quality test. This file become the standard against which other output results are compared.

If, at step 212, the generated graphics do not conform with an expected set of results or required standards, at step 216, for example, a developer may evaluate the parameter list and/or evaluate the application software, since it may be possible that programming bugs or contaminated files are contributing to generating the discrepancy between the generated graphics and the expected results.

If at step 210, the graphics are not generated, as described above, the developer may have to evaluate the parameter list and/or evaluate the application software. In the illustrated example, the model output file comprises graphics (e.g., bar code symbology). Other model output files having model output results may be generated by other application programs or computer systems. The model output results may, for example, include other graphics and/or data.

FIG. 2b illustrates an example of a second operational step associated with a software quality control system 200 for bar code generation software according to an embodiment of the present invention. Test program 220 sends a set of input parameters 222 to software application program 224, where software program 224 has been changed as a result of, for example, a software feature update. By running or executing the software program 224 based on input parameters 222, the program 224 generates a test output file 228 comprising test output results e.g., bar code symbology. If the integrity of the software program has not changed as a result of, for example, updating the software to generate new graphics, corrupted files, undetected viruses, software bugs, etc., the contents of the test output file should be the same as the model output file. Alternatively, it may also be possible that as program 224 executes input parameters 222, it may generate error messages 228 based on the use of incorrect input parameters 222.

If the software program 224 has been changed to include the generation of additional graphics or output results, the input parameters should be expanded to included additional parameters for testing the new graphics. When these additional parameters are executed by program 224, the additional graphics or output results may be generated. As previously described in relation to FIG. 2a, newly generated graphics are verified to ensure that they are in conformance with the correct specification before being stored in the model output file. If the newly generated graphics are not in conformance, the input parameter list 222 and/or the software program 224 may need editing or evaluation in order to generate the correct output result, e.g., graphic symbol.

FIG. 2c illustrates an example of a third operational step associated with a software quality control system 200 for bar code generation software according to an embodiment of the present invention. Once a model output file 230 comprising model output results 232 has been generated, it may be electronically (e.g., digitally) compared with a test output file 234 generated by the software program. The test output file include test output results 236 that are compared on a bit-by-bit basis with the model output results 232. For example, if the test output results generate graphics, each corresponding graphic from the test output results is compared with a corresponding graphic in the model output results on a bit-by-bit basis (e.g., in FIG. 2c, Graphic 1 of results 236 compared to Graphic 1 of results 232).

Once the electronic comparison is concluded, the results of the comparison is reported in a generated report 240. A checksum is generated for each of the model output files and the test output files. If the difference between these checksums is not zero, it is indicative that an error has occurred and there is a discrepancy between the output results of the test file and the model file. If such an error is detected, it is identified in the generated report 240, and at step 242, for example, the developer of programmer may be notified that the program is not generating the model output results that it should be generating. The problem may then be investigated and, thus, corrected. If at step 242 no error is detected as a result of the model output results and test output results being the same, the software program may be approved.

While the invention has been described and illustrated in connection with preferred embodiments, many variations and modifications as will be evident to those skilled in this art may be made without departing from the spirit and scope of the invention, and the invention is thus not to be limited to the precise details of methodology or construction set forth above as such variations and modifications are intended to be included within the scope of the invention. Except to the extent necessary or inherent in the processes themselves, no particular order to steps or stages of methods or processes described in this disclosure, including the Figures, is implied. In many cases the order of process steps may be varied without changing the purpose, effect or import of the methods described.

1. A method of verifying a computer system, the method comprising:
(a) generating one or more first output results by applying one or more input parameters to a first computer system;
(b) verifying that the one or more first output results match one or more expected results;
(c) generating one or more second output results by applying the one or more input parameters to a second computer system; and
(d) electronically comparing the verified one or more first output results with the one or more second output results.

2. The method according to claim 1, wherein the first computer system and the second computer system are the same.

3. The method according to claim 1, wherein the first computer system and the second computer system are different.

4. The method according to claim 1, further comprising reporting a result based on the electronic comparison, wherein the reported result indicates an error based upon the electronic comparison detecting a discrepancy between the verified one or more first output results with the one or more second output results.

5. The method according to claim 1, wherein the one or more first output results comprise at least one graphic output.

6. The method according to claim 5, wherein the at least one graphic output comprises a machine-readable symbol graphic.

7. The method according to claim 1, wherein electronically comparing the verified one or more first output results with the one or more second output results comprises a digital bit-by-bit comparison between the one or more first output results and the one or more second output results.

8. The method according to claim 7, wherein the digital bit-by-bit comparison comprises generating a checksum between each bit-by-bit component within the verified one or more first output results and the one or more second output results.

9. The method according to claim 1, wherein verifying that the one or more first output results match the one or more expected results comprises visually comparing the one or more first output results with the one or more expected results.

10. The method according to claim 1, wherein verifying that the one or more output results match the one or more expected results comprises using a device to determine that the one or more first output results match the one or more expected results.

11. The method according to claim 10, wherein the device comprises a bar code verifier device.

12. The method according to claim 1, further comprising adding additional parameters to the one or more input parameters based on modifications to the second computer system, wherein the additional parameters generate additional one or more first output results.

13. The method according to claim 10, wherein the additional one or more first output results are verified to ensure that the additional one or more first output results match additional one or more expected results.

14. A method of verifying a first computer system, implemented by a second computer system, the method comprising:
(a) generating at the first computer system one or more first output results by applying one or more input parameters to the first computer system;
(b) verifying at the first computer system that the one or more first output results match one or more expected results;
(c) generating at the second computer one or more second output results by applying the one or more input parameters to the second computer system; and
(d) electronically comparing at the second computer system the verified one or more first output results with the one or more second output results.

15. A system comprising a first computer system, for verifying a second computer system, the first computer system programmed to:
(a) generate one or more first output results by applying one or more input parameters to the first computer system;
(b) verify that the one or more output results match one or more expected results;
(c) generate one or more second output results by applying the one or more input parameters to the second computer system; and
(d) electronically compare the verified one or more first output results with the one or more second output results.

16. A computer readable medium or media having programming stored thereon that when executed by at least one computer system comprising a first computer system and a second computer system causes the at least one computer system to:
(a) generate one or more first output results by applying one or more input parameters to the first computer system;
(b) verify that the one or more first output results match one or more expected results;
(c) generate one or more second output results by applying the one or more input parameters to the second computer system; and
(d) electronically compare the verified one or more first output results with the one or more second output results.

17. A computer verification system, the system comprising:
(a) a means for generating one or more first output results by applying one or more input parameters to a first computer system;
(b) a means for verifying that the one or more first output results match one or more expected results;
(c) a means for generating one or more second output results by applying the one or more input parameters to a second computer system; and
(d) a means for electronically comparing the verified one or more first output results with the one or more second output results.
